(19) United States
(12) Patent Application Publication
(10) Pub. No.: US 2009/0078305 A1
(43) Pub. Date: Mar. 26, 2009

(54) SOLAR CELL AND SOLAR CELL MODULE

(75) Inventor: Takeshi NISHIWAKI, Kobe City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/207,637

(22) Filed: Sep. 10, 2008

(30) Foreign Application Priority Data
Sep. 25, 2007 (JP) JP2007-246442

(51) Int. Cl. H01L 31/0224

(52) U.S. Cl. 136/249; 136/256; 257/E31.124

(57) ABSTRACT

Pressure applied when connecting a solar cell to a wiring material becomes uneven due to the uneven shape of a semiconductor wafer and thereby causes cell cracks. A solar cell of the invention is configured by forming a connection electrode in a first direction having a smaller degree of unevenness in the thickness of the semiconductor wafer, and by forming a finger electrode in a second direction having a higher degree of unevenness in the thickness thereof. Hence a solar cell that allows uniform application of pressure when being connected with the wiring material can be provided. Moreover, by employing the solar cell of the invention, pressure is uniformly applied to the semiconductor wafer in a process of connecting multiple solar cells to one another. Thus, it is possible to provide a solar cell module achieving improvement in output and reliability while preventing defects such as cell breaks or cracks.

### CROSS REFERENCE TO RELATED APPLICATIONS

This application claims priority based on 35 USC 119 from prior Japanese Patent Application No. P2007-246442 filed on Sep. 25, 2007, the entire contents of which are incorporated herein by reference.

### BACKGROUND OF THE INVENTION

1. Field of the Invention

The present invention relates to a solar cell and to a solar cell module including multiple solar cells electrically connected to one another by wiring materials.

2. Description of Related Art

As shown in a conceptual cross-sectional view of FIG. 5, solar cell module 1 is formed in a configuration wherein multiple solar cells 3 electrically connect to one another by wiring materials 2 and are sealed between front surface protection member 103 and back surface protection member 104 by sealing layer 105.

As shown in a plan view of FIG. 6, which is viewed from a light receiving surface side, solar cell 3 includes photoelectric converter 5 having a photoelectric conversion function and power collecting electrode 4 provided on a light incident surface of photoelectric converter 5. Power collecting electrode 4 includes multiple line-shaped finger electrodes 4A and connection electrodes 4B. Finger electrodes 4A are arranged in parallel with one another substantially across the entire region of the light incident surface of photoelectric converter 5. Connection electrodes 4B are disposed so as to extend perpendicular to a longitudinal direction of finger electrodes 4A. Moreover, wiring materials 2 are bonded onto connection electrodes 4B in an extending direction (longitudinal direction) of connection electrodes 4B by using conductive adhesive 7 such as a solder or a conductive resin adhesive.

Meanwhile, as existing photoelectric converters 5, converters formed of semiconductor wafers using crystalline semiconductor materials such as single-crystal silicon or polycrystalline silicon are known. These semiconductor wafers made of crystalline semiconductor materials are manufactured by firstly forming a columnar ingot with the Czochralski (CZ) method, the floating zone (FZ) method, the ribbon method or the casting method, and then by cutting the thus formed ingot into pieces each having a predetermined thickness by of a wire saw. Such a technique is disclosed in Japanese Unexamined Patent Application Publication No. Hei. 7-205140, for example.

### SUMMARY OF THE INVENTION

An embodiment provides a solar cell that comprises: a photoelectric converter; and a power collecting electrode disposed on one principal surface of the photoelectric converter, the power collecting electrode including a connection electrode extending in one direction and a finger electrode extending in a direction orthogonal to the one direction and being electrically connected to the connection electrode, wherein the photoelectric converter includes a semiconductor wafer, the semiconductor wafer has thickness distribution in which a difference between a maximum value and a minimum value of thicknesses in a cross section in a first direction of the semiconductor wafer is smaller than a difference between a maximum value and a minimum value of thicknesses in a cross section in a second direction orthogonal to the first direction, and the connection electrode is disposed on the one principal surface of the photoelectric converter so as to extend in the first direction.

As described above, according to the solar battery of an example of the embodiment above, the connection electrode is disposed on the solar cell in the direction in which the thickness of the semiconductor wafer is uniform. Thus, it is possible to apply uniform pressure when connecting the connection electrode to the wiring material, and thereby to employ the solar cell that can prevent adhesion failure in a connecting process and presenting such as breaks, chips or cracks. Here, the thickness of the semiconductor wafer can be measured by a laser displacement gauge, for example.

Another embodiment provides a solar cell module that comprises: multiple solar cells arranged along an arrangement direction; and a wiring material extending in the arrangement direction and configured to electrically connect adjacent solar cells, wherein the solar cell comprises: a photoelectric converter; and a connection electrode disposed on one principal surface of the photoelectric converter and connected to the wiring material, wherein the photoelectric converter includes a semiconductor wafer, the semiconductor wafer has thickness distribution in which a difference between a maximum value and a minimum value of thicknesses in a cross section in a first direction of the semiconductor wafer is smaller than a difference between a maximum value and a minimum value of thicknesses in a cross section in a second direction orthogonal to the first direction, the multiple solar cells are arranged so that the connection electrode extends in the first direction, and the wiring material connect to the connection electrode in the extending direction of the connection electrode.

According to the solar battery of the above embodiment, the connection electrode is disposed on the solar cell in the direction in which the thickness of the semiconductor wafer is uniform. Thus, it is possible to apply uniform pressure when connecting the connection electrode to the wiring material, and thereby to employ the solar cell that can prevent adhesion failure in a connecting process and prevent defects such as breaks, chips or cracks. Here, the thickness of the semiconductor wafer can be measured by a laser displacement gauge, for example. Moreover, the wiring material is connected in the extending direction of the connection electrode. Accordingly, in the process of connecting the multiple solar cells, it is possible to apply uniform pressure to the semiconductor wafer and thereby to provide the solar cell module with improved reliability.

In this way, by disposing the connection electrode in the direction in which the thickness of the semiconductor wafer is uniform, it is possible to offer the solar cell that allows uniform application of pressure when connecting the wiring material to the connection electrode. Moreover, the wiring material is connected in the extending direction of the connection electrode. Thus, it is possible to apply uniform pressure to the semiconductor wafer in the process of connecting the multiple solar cells, and thereby to provide a solar cell module with improved reliability.

### BRIEF DESCRIPTION OF THE DRAWINGS

FIGS. 1A and 1B are plan views each showing a solar cell according to an embodiment.

FIG. 2 is a cross-sectional view for explaining a layout relationship among power collecting electrodes and a semiconductor wafer of a solar cell module according to an embodiment.

FIG. 3 is another cross-sectional view for explaining the layout relationship among the power collecting electrodes and the semiconductor wafer of the solar cell module according to an embodiment.

FIGS. 4A and 4B are plan views each showing a connection relationship among connection electrodes, conductive adhesive, and wiring materials of the solar cell module of an embodiment.

FIG. 5 is a schematic view for explaining the solar cell module.

FIG. 6 is a plan view of an existing solar cell viewed from a light receiving surface side.

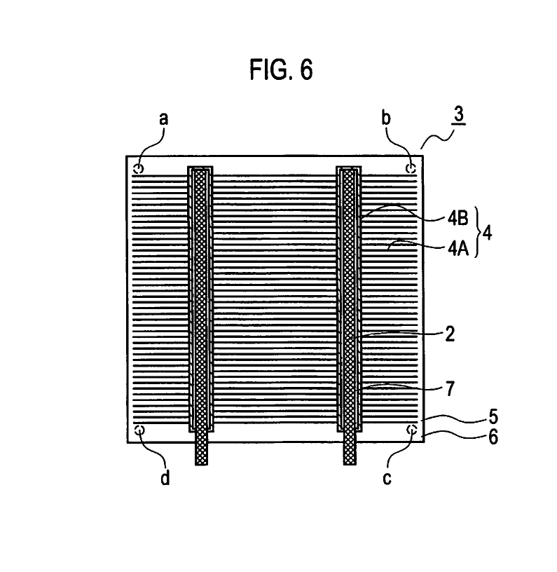

FIGS. 7A to 7C are conceptual explanatory views for an existing method of manufacturing a semiconductor wafer.

FIG. 8 is a view showing a piece of a semiconductor wafer, which is cut with a wire saw, viewed from six directions.

FIGS. 9A and 9B are explanatory views for a process to connect a wiring material to a solar cell.

### DETAILED DESCRIPTION OF EMBODIMENTS

An embodiment of the invention will be described below based on the drawing. The drawing is only an example, and the invention is not limited to proportions of sizes and the like in the drawing. Accordingly, specific sizes and the like have to be judged by considering the following description.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### (Finding Problems of Existing Method of Manufacturing a Solar Cell Module)

As a result of earnest studies conducted by the inventor, it is found out that a semiconductor wafer manufactured by an existing method has a larger difference between a maximum value and a minimum value of thicknesses in a cross section taken along one direction of the semiconductor wafer than a difference between a maximum value and a minimum value of thicknesses in a cross section taken along the other direction thereof substantially orthogonal to the one direction, thus causing lower manufacturing yields for solar cell modules. More precisely, the existing semiconductor wafer has unevenness in such a manner that a thickness in a cross section of semiconductor wafer 6 taken along the one direction is gradually increased from one end to the other end. The reason for causing such unevenness is speculated as follows.

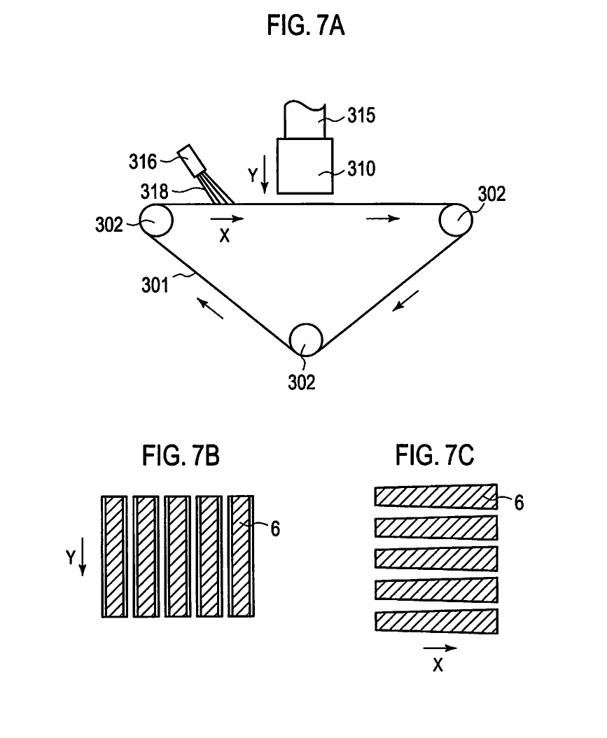

FIGS. 7A to 7C are conceptual explanatory views for the existing method of manufacturing a semiconductor wafer. In FIG. 7A, reference numeral 301 denotes wires for cutting ingot 310. Multiple wires 301 are wound around roller 302 at predetermined intervals. Wires 301 travel at high speed in a traveling direction as indicated by arrow X in the drawing by rotating roller 302. Ingot 310 is fixed to slice base 315 and moves in a feed direction for cutting as indicated by arrow Y in the drawing by an unillustrated movement mechanism. Meanwhile, reference numeral 316 denotes an abrasive grain supply nozzle configured to supply a working fluid containing abrasive grains to wires 301 while traveling. Thus, by rotating roller 302 to allow wires 301 to travel at high speed in the traveling direction while moving ingot 301 in the feed direction for cutting, semiconductor wafers 6 each having a predetermined thickness are cut out of ingot 310.

FIG. 7B is a conceptual explanatory view of ingot 310 at the time of cutting, which is viewed from the direction indicated by arrow X, and FIG. 7C is a conceptual explanatory view of ingot 310 at the time of cutting, which is viewed from the direction indicated by arrow Y.

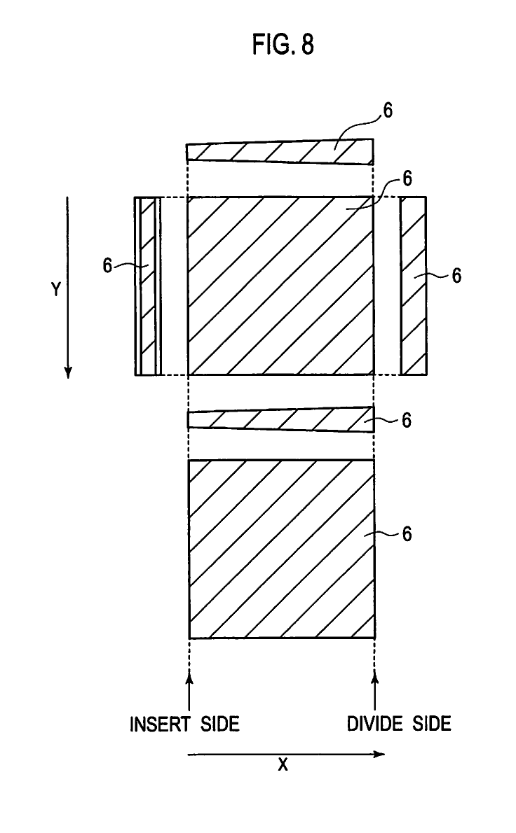

As shown in FIG. 7A, working fluid 318 containing the abrasive grains is supplied from abrasive grain supply nozzle 316 to wires 301 that are traveling at high speed. Working fluid 318 moves in the direction indicated by arrow X in the drawing along the travel of wires 301, and is used for cutting ingot 310. For this reason, the concentration of abrasive grains contained in working fluid 318 gradually decreases as the cutting operation of ingot 310 proceeds, thus causing a decrease in processing width. As a result, as shown in FIGS. 7B and 7C, the cross section of semiconductor wafer 6 in the traveling direction (indicated by arrow X) of wires 301 becomes smaller on the side where wires 301 are cut in and becomes larger on the side where semiconductor wafer 6 is cut out. In contrast, the cross section of semiconductor wafer 6 in the feed direction for cutting (the direction indicated by arrow Y) of ingot 310 becomes relatively uniform because the distance to abrasive grain supply nozzle 316 remains almost the same. As a result, as shown in FIG. 8 illustrating semiconductor wafer 6 viewed from 6 directions, there is manufactured semiconductor wafer 6 having thickness distribution in which the difference between the maximum value and the minimum value of thicknesses in the direction of arrow X is larger than the difference between the maximum value and the minimum value of thicknesses in the direction of arrow Y.

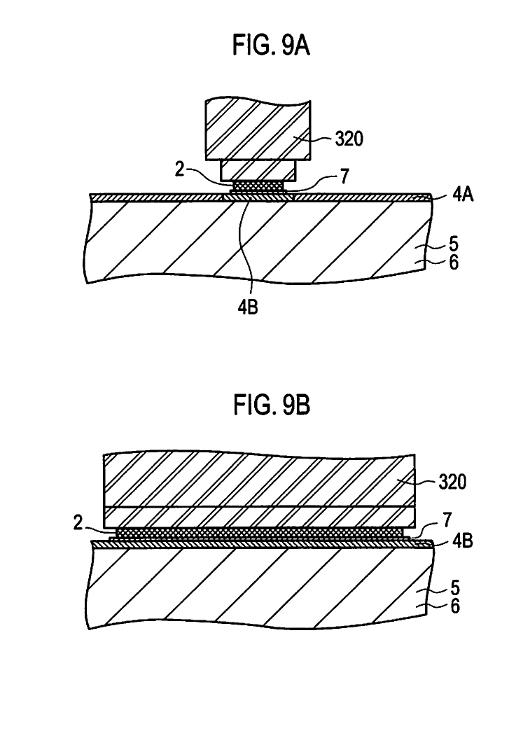

The following problems occur when solar cell module 1 is manufactured from solar cell 3 fabricated by use of semiconductor wafer 6 made by the above-described manner. FIGS. 9A and 9B show a process to connect wiring material 2 to solar cell 3. Here, FIG. 9A is a view from a longitudinal direction of wiring material 2 while FIG. 9B is a lateral direction view of wiring material 2. As shown in these drawings, pressure is applied by block 320 in the drawing to wiring material 2 so as to bond wiring material 2 to solar cell 3. In this case, if solar cell 3 forms by semiconductor wafer 6 having the above-described thickness distribution and then solar cell module 1 is manufactured by bonding to wiring material 2 to solar cell 3, the pressure to be applied from block 320 to solar cell 3 may become uneven in some places. As a consequence, there arise risks of defects such as a break, a chip or a crack on solar cell 3 or adhesion failure. Specifically, if wiring material 2 is bonded onto solar cell 3 in the direction having a larger degree of uneven thickness, excessive pressure is applied to a region having a large thickness. Thus, solar cell 3 may cause defects such as a break, a chip or a crack. Meanwhile, the pressure may become insufficient in a region having a small thickness, and adhesion failure of wiring material 2 is apt to occur. Manufacturing yields or reliability of solar cell modules may deteriorate by the above-described reasons.

### (Structure of Solar Cell Module)

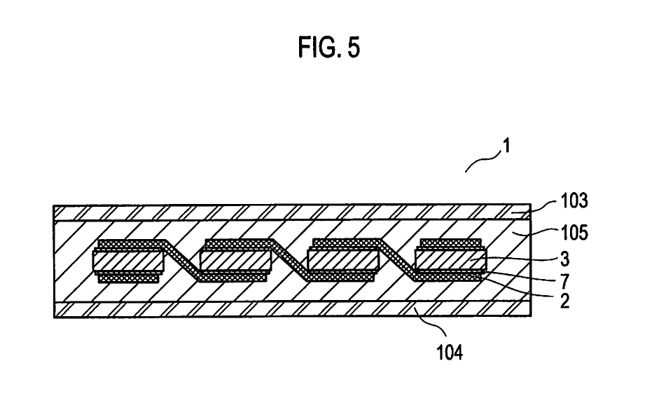

Solar cell module 1 according to an embodiment will be described with reference to a schematic drawing shown in FIG. 5.

In FIG. 5, reference numeral 3 denotes solar cells that electrically connect to one another by wiring materials 2. Wiring material 2 is made of a metallic material such as copper foil. Surfaces thereof may be coated with a conductive material by, for example, tin plating. Translucent front surface protection member 103 is bonded on a light receiving surface side of solar cell 3 by translucent sealant 105. Front surface protection member 103 is formed by a translucent material such as glass or translucent plastic. Meanwhile, back surface protection member 104 is bonded on a back surface side of solar cell 3 by sealant 105. Back surface protection member 104 consists of, for example, a resin film such as polyethylene terephthalate (PET) or a laminated film formed by sandwiching Al foil between resin films. Meanwhile, sealant 105 is made of translucent resin such as ethylene-vinyl acetate (EVA) or polyvinyl butyral (PVB), which also seals solar cells 3. Moreover, an unillustrated terminal box for extracting electric power is disposed on a back surface of back surface protection member 104. Further, a frame body is fitted to the outer periphery of the solar cell module as needed.

### (Structure of Solar Cell)

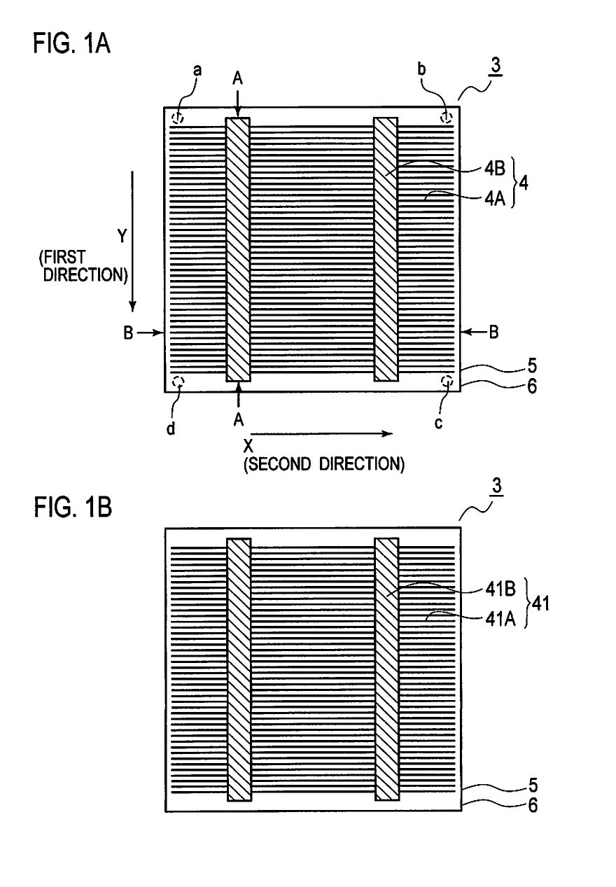

As shown in plan views of FIGS. 1A and 1B, solar cell 3 includes photoelectric converter 5 and power collecting electrodes 4 and 41 respectively on the light receiving and back surfaces of photoelectric converter 5. Photoelectric converter 5 includes semiconductor wafer 6 of one conductivity type and a semiconductor region of the other conductivity type, and contains either a p-n junction or a p-i-n junction. Meanwhile, the semiconductor material for forming semiconductor wafer 6, can be single-crystal silicon, polycrystalline silicon, other crystalline semiconductor materials, compound semiconductor materials such as GaAs, or other semiconductor materials for solar batteries that can be formed into a wafer shape.

As shown in the plan view of FIG. 1A, power collecting electrodes 4 formed on the light receiving surface side of photoelectric converter 5 include multiple finger electrodes 4A and bus bar electrodes. Finger electrode 4A is configured to gather electron and hole carriers generated by photoelectric converter 5 using incident light. The bus bar electrode is configured to collect the carriers gathered by finger electrodes 4A. The bus bar electrodes also function as connection electrodes 4B connected by wiring materials 2. FIG. 1B is a plan back surface side view of solar cell 3. Power collecting electrodes 41 formed on the back surface side include multiple finger electrodes 41A and bus bar electrodes. Finger electrode 41A is configured to gather electron and hole carriers, while the bus bar electrode is configured to collect the carriers gathered by finger electrodes 41A. The bus bar electrodes also function as connection electrodes 41B connected by wiring materials 2. Note that power collecting electrode 41 on the back surface side may apply various kinds of configurations without limitations to the foregoing. For example, it is also possible to provide a power collecting electrode by applying a conductive agent on the entire back surface.

Power collecting electrodes 4 and 41 are made of a thermosetting conductive paste that contains epoxy resin as binder and conductive particles as filler, for example. In the case of a single-crystal silicon solar cell, a polycrystalline silicon solar cell, or the like, power collecting electrodes 4 can be formed from a baking-type paste that contains metal powder such as silver or aluminum, glass frit, an organic vehicle, and the like without limitations to the foregoing. Alternatively, power collecting electrodes 4 can be formed from ordinary metal such as silver or aluminum.

### (Layout of Power Collecting Electrode)

A layout relationship between photoelectric converter 5 and power collecting electrode 4 of this embodiment will be described below in detail. Solar cell 3 of the embodiment includes photoelectric converter 5 having semiconductor wafer 6, and power collecting electrodes 4 and 41 respectively provided on the light receiving surface and the back surface of this photoelectric converter 5. Photoelectric converter 5 is formed of semiconductor wafer 6 such as a single-crystal silicon wafer and the semiconductor region of the opposite conductivity type formed on this wafer by a thermal diffusion method or a film-forming method. The semiconductor region of the opposite conductivity type, formed by the thermal diffusion method or the film-forming method, has a principal plane that is substantially parallel to the principal plane of semiconductor wafer 6. Accordingly, photoelectric converter 5 is shaped substantially equal to that of semiconductor wafer 6. Unevenness in the thickness of photoelectric converter 5 is almost equivalent to unevenness in the thickness of semiconductor wafer 6.

As shown in FIG. 8, semiconductor wafer 6 constituting photoelectric converter 5 has the thickness distribution in which the difference between the maximum value and the minimum value of thicknesses of the cross section taken along the direction of arrow X of semiconductor wafer 6 is larger than the difference between the maximum value and the minimum value of thicknesses of the cross section taken along the direction of arrow Y of semiconductor wafer 6. More precisely, as shown, the thickness of semiconductor wafer 6 in the direction of arrow Y remains almost the same on one end and on the other end, whereas the thickness of semiconductor wafer 6 in the direction of arrow X gradually increases from one end to the other. Accordingly, the thickness of semiconductor wafer 6 of the cross section taken along the direction of arrow X becomes maximum on the one end side in a second direction and becomes minimum on the other end side, when the direction of arrow Y representing the small difference between the maximum value and the minimum value of thicknesses of semiconductor wafer 6 is defined as a first direction while the direction of arrow X representing the large difference between the maximum value and the minimum value of thicknesses of semiconductor wafer 6 is defined as the second direction. In this embodiment, as shown in FIGS. 1A and 1B, connection electrodes 4B are formed so as to extend in the first direction having the small difference between the maximum value and the minimum value of thicknesses of semiconductor wafer 6, while finger electrodes 4A are formed so as to extend in the second direction which is orthogonal to the first direction.

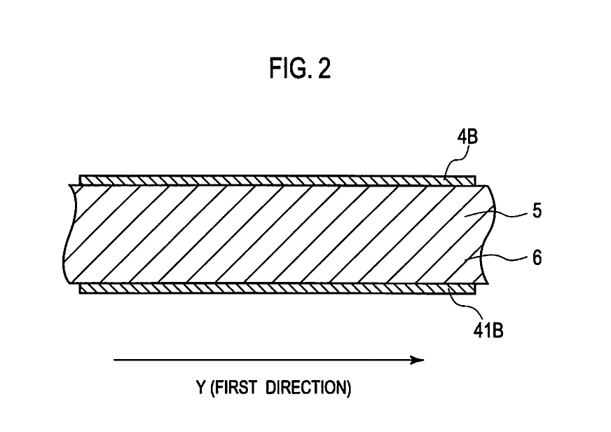

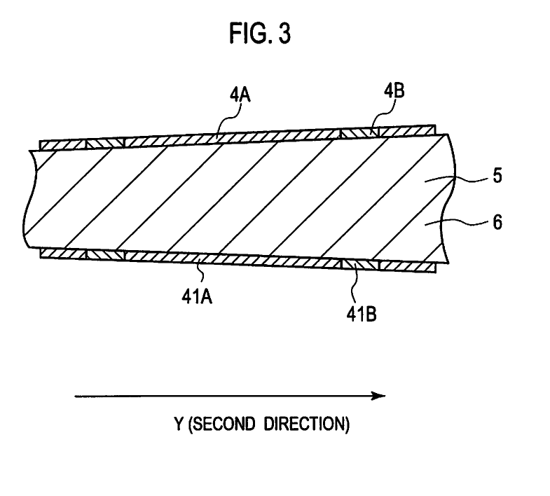

Thus, as shown in FIG. 2, illustrating a cross-sectional view taken along A-A line of the plan view shown in FIG. 1A, the thickness distribution of the cross section of the semiconductor wafer in the extending direction of connection electrodes 4B becomes substantially uniform. On the contrary, as shown in FIG. 3, illustrating a cross-sectional view taken along B-B line of the plan view shown in FIG. 1A, the thickness of the photoelectric converter in the extending direction of finger electrodes 4A is uneven and the thickness gradually increases from one end to the other.

As described above, according to solar cell 3 of this embodiment, connection electrodes 4B extend in the first direction having the small difference between the maximum value and the minimum value of thicknesses of the semiconductor wafer. Accordingly, the pressure to be applied to connection electrode 4B when connecting wiring material 2 onto connection electrode 4B is uniformly applied on almost the entire surface of connection electrode 4B. Hence, according to this embodiment, defects such as broken cells or cracks at the time of bonding of wiring material 2 and adhesion failure of wiring material 2 attributable to insufficient pressure can be prevented.

### (Layout of Wiring Materials)

Next, a connection relationship between the aforementioned solar cells 3 will be detailed.

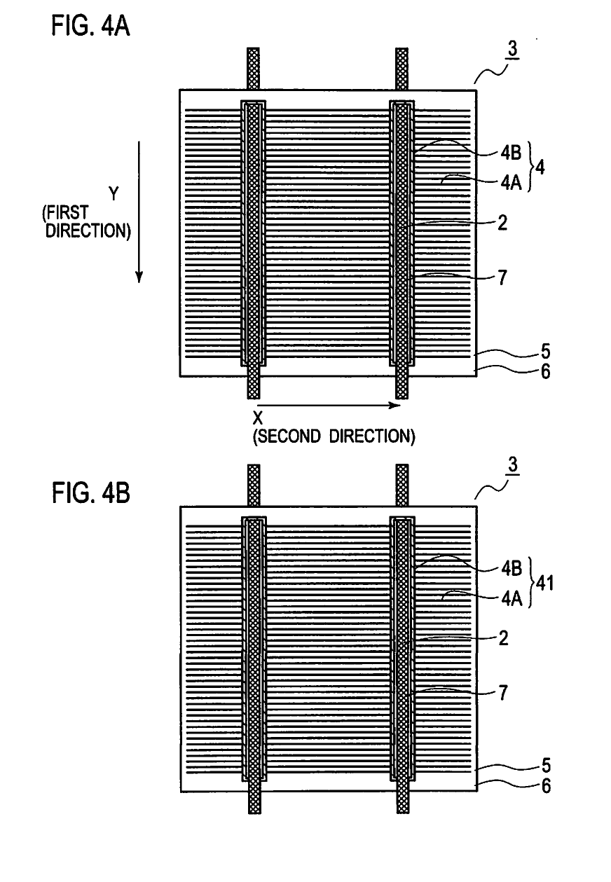

FIGS. 4A and 4B are top views each showing a connection relationship between solar cells 3 by using wiring material 2 according to this embodiment. Wiring material 2 is connected to connection electrode 4B to extend in the first direction having the small difference between the maximum value and the minimum value of thicknesses by use of conductive adhesive 7 applied on the upper surface of connection electrode 4B.

Thus, the pressure applied when connecting wiring material 2 onto connection electrode 4B is uniformly on almost the entire surface of connection electrode 4B. Hence, according to solar cell module 1 of this embodiment, adhesion failure between wiring material 2 and connection electrode 4B and defects such as broken cells, chips or cracks can be prevented. Thereby, solar cell module 1 with improved yields and excellent reliability can be provided.

### EXAMPLE

A solar cell and module embodiment are fabricated as follows.

### <Process 1> Formation of Photoelectric Converter

First, an n-type single-crystal silicon wafer, from which impurities are removed, having a thickness of 100 μm and a resistivity of about 1 Ω·cm is cleaned. Next, an i-type amorphous silicon layer having a thickness of about 5 nm and a p-type amorphous silicon layer having a thickness of about 5 nm are formed in this order on a top surface of the n-type single-crystal silicon wafer substantially parallel to semiconductor wafer 6 by a radio frequency plasma chemical vapor deposition (RF plasma CVD) method.

Next, an i-type amorphous silicon layer having a thickness of about 5 nm and an n-type amorphous silicon layer having a thickness of about 5 nm are formed in this order on a bottom surface of the n-type single-crystal silicon wafer substantially parallel to semiconductor wafer 6. Here, the i-type amorphous silicon layer and the n-type amorphous silicon layer are formed by a process similar to that used for forming the i-type and p-type amorphous silicon layers, respectively.

Next, an indium tin oxide (ITO) film having a thickness of about 100 nm is formed on each of the p-type and n-type amorphous silicon layers substantially parallel to semiconductor wafer 6 by a magnetron sputtering method.

Photoelectric converter 5 of the solar cell of the example is fabricated thereby.

### <Process 2> Formation of Power Collecting Electrodes

Next, power collecting electrode 4 on the light receiving surface side is formed on the surface of the ITO film provided on the light receiving surface side of the photoelectric converter by screen printing of silver paste of either an epoxy thermosetting type or a sintering-type. Here, the thickness is measured on a position located about 6 mm away from an end of a substrate indicated by the dotted circle in FIG. 1A. Incidentally, a laser displacement gauge having two heads is used for measuring thickness in a noncontact manner. Then, power collecting electrodes 4 are formed so that the thickness distribution of semiconductor wafer 6 and the layout relationship of connection electrodes 4B satisfy the above-described predetermined relationship. More precisely, two connection electrodes 4B having widths of 1.8 mm and heights of 0.04 mm are formed so as to extend in the first direction of the semiconductor wafer. Multiple finger electrodes 4A, having widths of 0.1 mm, heights of 0.04 mm, and pitches of 2 mm are formed on the entire region of solar cell 3 so as to extend in the second direction of the semiconductor wafer and to cross to connection electrodes 4B. Meanwhile, power collecting electrode 41 on the bottom surface side is formed similarly to power collecting electrode 4 on the light receiving surface side.

A sample of the solar cell of the example is fabricated by the above-described process.

### <Process 3> Bonding of Wiring Materials

Wiring material 2 is copper foil of 2 mm width, 0.15 mm thickness, and with solder as conductive adhesive on surfaces of the copper foil. Then, wiring materials 2 are disposed on connection electrodes 4B and 41B respectively on the top and bottom surfaces of solar cells 3, and sandwich connection electrodes 4B and 41B from above and below. Thereafter, connection electrodes 4B and 41B are bonded to wiring materials 2 by conductive adhesive 7 (solder) by heating while applying predetermined pressure. Here, a resin conductive adhesive may also be used as conductive adhesive instead of solder. In this case, the writing materials may be copper foil coated with solder.

### COMPARATIVE EXAMPLE

As a comparative example, a solar cell sample is formed similarly except that formation of power collecting electrodes does not consider unevenness in thickness of the semiconductor wafer.

### (Results)

First, measurements of photoelectric converter thicknesses are performed on 10 samples of the solar cells according to the comparative example. Each of positions a to d are located 6 mm away from the ends of the corresponding substrate. Thereby, average values of the differences in thicknesses between positions a and d, between positions b and c, between positions a and b, and between positions c and d are obtained. Results thereof are shown in Table 1. Here, the semiconductor region of the opposite conductivity type formed on the semiconductor wafer of the photoelectric converter is extremely thin as compared to the semiconductor wafer. Further, the above-described semiconductor region has a principal plane substantially parallel to that of the semiconductor wafer. Accordingly, thickness variability of the photoelectric converter becomes substantially equal to that of the semiconductor wafer. Here, the single-crystal silicon wafer used for the samples has a size of about 125 mm×125 mm.

TABLE 1

| | Average value of difference | | | |
|---|---|---|---|---|
| | in thickness [μm] | | | |
| | \|a − d\| | \|b − c\| | \|a − b\| | \|c − d\| |
| Comparative example | 6.9 | 7.6 | 7.1 | 11.1 |
| Example | 2.6 | 1.5 | 16.0 | 15.3 |

As shown in Table 1, when the comparative example is compared with the example, the differences in thicknesses |a-d| and |b-c| of the photoelectric converter in the direction along connection electrodes 4B and 41B of the solar cell in the example are smaller than those in the comparative example. Moreover, the differences in the thicknesses |a-d| and |b-c| of the photoelectric converter in the direction along connection electrodes 4B and 41B of the solar cell in the example are smaller than the differences in the thicknesses |a-b| and |c-d| of the photoelectric converter in the direction along finger electrodes 4A and 41A. Meanwhile, in the sample of the comparative example, the power collecting electrodes are arranged while the thickness distribution of the photoelectric converter is not taken into consideration, the differences in the thicknesses |a-d| and |b-c| in the direction along connection electrodes 4B and 41B are approximately equal to the differences in the thicknesses |a-b| and |c-d| in the direction along finger electrodes 4A and 41A.

Next, the wiring materials are connected to 1000 samples of solar cells according to the comparative example and the example. Here, yields are obtained by visually checking products having cell breaks. Results thereof are shown in Table 2.

TABLE 2

| | Yields (%) |
|---|---|
| Comparative example | 95.5 |
| Example | 98.8 |

As shown in the table, the connection process with the wiring materials using the solar cells according to the example shows higher manufacturing yield. In essence, since the differences in the thicknesses of the photoelectric converter in the direction of connection electrodes 4B and 41B of the solar cell in the example are smaller than those in the comparative example, the pressure is more uniformly applied when connecting the solar cell to the wiring material in the example than in the comparative example. Thereby, the manufacturing yield is speculated to improve as shown in Table 2 because the occurrence of cell breaks becomes lower in the example.

Further, solar cells according to the comparative example and the example are fabricated similarly to the above-described processes while employing a semiconductor wafer having a thickness of 90 μm, which is thinner than the above-described samples. Thereafter, the wiring materials are connected to the solar cells according to the comparative example and the example, and then yields are obtained by visually checking products having cell breaks. As a result, the manufacturing yield of the comparative example is equal to 90.5% while the manufacturing yield of the example is equal to 96.6%. From this result, in the solar cell of this example, it is estimated that the effect of preventing cell breaks during connection of wiring material increases as the semiconductor wafer thickness decreases.

As described above, the following operations and effects are achieved according to the embodiment and the example. The solar cell of the embodiment is configured to form the connection electrodes in the first direction having small differences between maximum and minimum semiconductor wafer thicknesses and with the finger electrodes in the second direction having the large differences between maximum and minimum semiconductor wafer thicknesses. In this way, as compared to an existing case where a solar cell is fabricated while the thickness of the semiconductor wafer is not taken into consideration, it is possible to fabricate the solar cell that allows uniform application of the pressure when connecting the wiring material.

Moreover, by using solar cells of the embodiment, pressure is applied more uniformly to the semiconductor wafer when connecting multiple solar cells to one another. Thereby a solar cell module can be formed of higher reliability by preventing defects such as cell breaks and cracks.

### Other Embodiments

In this embodiment, description has been given of semiconductor wafer 6 having the thickness distribution in which the thickness of semiconductor wafer 6 is gradually increased in the second direction, for example. However, the present invention is not limited to semiconductor wafer 6 having this type of thickness distribution. For example, the thicknesses of the cross section of the semiconductor wafer (the photoelectric converter) may be measured in multiple positions along one direction by using a laser displacement gauge. The differences between maximum and minimum thicknesses are obtained from these measurements. This measurement process is repeated while changing the direction. From the results, the direction of minimum thickness difference of semiconductor wafer 6 can be defined as a first direction and the direction orthogonal thereto as a second direction. In this case, connection electrode 4B also extends in the direction having a smaller degree of unevenness in the thickness of semiconductor wafer 6. Accordingly, similar effects can be obtained.

Moreover, the solar cell module employing the solar cells according to any of these embodiments can prevent adhesion failure and defects such as cell breaks, chips or cracks. Thus, it is possible to provide solar cell module 1 with improved yields and excellent reliability.

The unevenness in semiconductor wafer 6 thickness is caused by cutting ingot 310. Accordingly, this problem occurs irrespective of the shape of semiconductor wafer 6. In this embodiment, semiconductor wafer 6 has a rectangular shape. However, similar effects can be obtained for rectangular semiconductor wafer 6, whose corners are subjected to processing such as chamfering, for circular semiconductor wafer 6 or circular semiconductor wafer 6 formed into another shape such as a rectangle, or for semiconductor wafer 6 of a polygonal shape, a circular arc shape, and so forth, as long as connection electrodes 4B are disposed so as to extend in the first direction having minimum thicknesses variability. Finger electrodes 4A are disposed so as to extend in the second direction having the large difference between the maximum value and the minimum value of thicknesses.

The wire saw cutting method causes unevenness in semiconductor wafer 6 thickness. However, similar effects can be naturally obtained for cutting semiconductor wafer 6 by other methods such as a laser or plasma, as long as connection electrodes 4B extend in the first direction having minimum thickness variability and finger electrodes 4A are extend in the second direction having the large difference between the maximum value and the minimum value of thicknesses.

The invention includes other embodiments in addition to the above-described embodiments without departing from the spirit of the invention. The embodiments are in all respects illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell comprising:
a photoelectric converter; and
a power collecting electrode disposed on a principal surface of the photoelectric converter, the power collecting electrode including a connection electrode extending in one direction and a finger electrode extending in a direction orthogonal to the one direction and electrically connected to the connection electrode,
wherein the photoelectric converter includes a semiconductor wafer, thickness variability in a first direction of the semiconductor wafer is smaller than thickness variability in a second direction orthogonal to the first direction,
the connection electrode is disposed on the principal surface of the photoelectric converter so as to extend in the first direction.

2. The solar cell of claim 1, wherein
the semiconductor wafer has thickness distribution in which a difference between a maximum value and a minimum value of thicknesses in a cross section in a first direction of the semiconductor wafer is smaller than a difference between a maximum value and a minimum value of thicknesses in a cross section in a second direction orthogonal to the first direction.

3. The solar cell of claim 1, wherein the thickness in the second direction of the semiconductor wafer varies gradually.

4. The solar cell of claim 1, wherein
the thickness of the semiconductor wafer in the second direction is maximum at one end in the second direction and becomes minimum at the other end.

5. The solar cell of claim 1, wherein
the power collecting electrode comprises thermosetting paste with conductive particles as filler

6. A solar cell module comprising:
a plurality of solar cells arranged a direction; and
wiring extending in the arranged direction and configured to electrically connect adjacent solar cells,
wherein each solar cell comprises:
a photoelectric converter; and
a connection electrode connected to the wiring and disposed on one principal surface of the photoelectric converter,
wherein the photoelectric converter includes a semiconductor wafer, thickness variability in a first direction of the semiconductor wafer is smaller than thickness variability in a second direction orthogonal to the first direction,
the plurality of solar cells are arranged with the connection electrode extending in the first direction, and
the wiring attaches the connection electrode in the first direction.

7. The solar cell module of claim 6, wherein the semiconductor wafer has thickness distribution in which a difference between a maximum value and a minimum value of thicknesses in a cross section in a first direction of the semiconductor wafer is smaller than a difference between a maximum value and a minimum value of thicknesses in a cross section in a second direction orthogonal to the first direction.

8. The solar cell module of claim 6, wherein the thickness in the second direction of the semiconductor wafer varies gradually.

9. The solar cell module of claim 6, wherein
the thickness of the semiconductor wafer in the second direction is maximum at one end in the second direction and becomes minimum at the other end.

10. The solar cell module of claim 6, wherein
the power collecting electrode comprises thermosetting paste with conductive particles as filler
